(19) United States
(12) Patent Application Publication
(10) Pub. No.: US 2012/0057406 A1
(43) Pub. Date: Mar. 8, 2012

(54) FLASH MEMORY APPARATUS

(75) Inventor: TAKAO AKAOGI, Cupertino, CA (US)

(73) Assignee: EON SILICON SOLUTION INC., CHU-PEI CITY (TW)

(21) Appl. No.: 12/874,491

(22) Filed: Sep. 2, 2010

(51) Int. Cl. G11C 16/04

(52) U.S. Cl. 365/185.13

(57) ABSTRACT

A flash memory apparatus includes a plurality of memory sectors and a plurality of path transistors, and each memory sector has a local low voltage line, and each path transistor corresponds to one of the memory sectors, and the path transistors are installed in an alignment direction of the memory sectors. One of the path transistors is installed between two adjacent memory sectors, whose gate is connected to a sector select signal line, and whose drain is connected to the local low voltage line of the corresponding memory sector, and whose source is connected to a global low voltage line, and the global low voltage line is installed at an angle substantially equal to 90 degrees across the gate, so as to save the area occupied by peripheral circuits in the path transistors, and lower the manufacturing cost of the flash memory apparatus.

### FIELD OF THE TECHNOLOGY

The present invention relates to a memory apparatus, in particular to a memory apparatus having a relatively small layout area.

### BACKGROUND

As semiconductor technologies advance, present memory apparatuses can store a large quantity of data. With reference to FIG. 1 for a circuit block diagram of a conventional flash memory apparatus, the memory apparatus 10 has a plurality of memory sectors SECTOR_1˜SECTOR_4 and a plurality of path transistors QAR1˜QAR4, and each of the memory sectors SECTOR_1˜SECTOR_4 has a plurality of word lines WL1˜WL8, a plurality of select signal lines SSEL1, SSEL2 and a plurality of global bit lines GBL1˜GBL4.

With reference to FIG. 2 for a circuit diagram of the memory sectors as depicted in FIG. 1, each circuit of the memory sectors SECTOR_1˜SECTOR_4 of FIG. 1 is the same as that of FIG. 2, and the word lines WL1˜WL8 are connected to a plurality of transistors Qᵢⱼ (where i and j are integers from 1 to 8) of the plurality of word strings WL_STRING_1˜WL_STRING_8 respectively. A local bit line LBLⱼ (where j is an integer from 1 to 8) is connected to a drain of the transistor Q₁ⱼ˜Q₈ⱼ and a drain of a select transistor QSELⱼ, and the word line WLᵢ (where i is an integer from 1 to 8) is connected to a gate of the transistor Qᵢ₁˜Qᵢ₈. A local low voltage line LARVSS is connected to a source of the transistor Qᵢⱼ (wherein i and j are integers from 1 to 8). The global bit line GBLₖ (wherein k is an integer from 1 to 4) is connected to a source of the select transistor QSEL₂ₖ₋₁, QSEL₂ₖ, and the select signal lines SSEL1 is connected to a gate of the select transistor QSEL₂ₖ₋₁ (wherein k is an integer from 1 to 4), and the select signal lines SSEL2 are connected to gates of the select transistors QSEL₂ₖ (where k is an integer from 1 to 4). The local low voltage line LARVSS is horizontally connected to a drain of each path transistor QAR, and a source of the path transistor QAR is connected to a global low voltage line GARVSS, and a gate of the path transistor QAR is controlled by a sector select signal line ASEL.

In FIGS. 1 and 2, each of the memory sectors SECTOR_1˜SECTOR_4 contains a local low voltage line LARVSS for connecting each source of a transistor that requires a low voltage. Traditionally, the local low voltage lines LARVSS of the memory sectors SECTOR_1˜SECTOR_4 are pulled out horizontally and connected to the global low voltage lines GARVSS through a plurality of path transistors QAR1˜QAR4 respectively. However, such arrangement has the drawbacks of increasing the layout area of the memory apparatus 10, reducing the using efficiency, and increasing the manufacturing cost of the memory apparatus 10.

### SUMMARY

In view of the drawbacks of the prior art, it is a primary objective of the present invention to provide a flash memory apparatus that can reduce the area occupied by periphery circuits and increase the utility efficiency of the area.

To achieve the foregoing and other objectives, the present invention discloses a flash memory apparatus comprising a plurality of memory sectors and a plurality of path transistors. Each of the memory sectors has a local low voltage line. The path transistors correspond to the memory sectors respectively, and the path transistors are installed in an alignment direction of the memory sectors, and one of the path transistors is installed between two adjacent memory sectors, and a gate of such path transistor is connected to the sector select signal line, and a drain of such path transistor corresponds to the local low voltage line of the memory sector, and a source of such path transistor is connected to the global low voltage line, wherein the global low voltage line is installed at an angle with a difference of 90 degrees across the gate of of such path transistor. A space already exists when the path transistor is installed between two memory sectors in accordance with the present invention, and thus it will not increase the original area of the memory unit, and the global low voltage line is installed at angle with a difference of 90 degrees across the gate of the path transistor. As a result, the area occupied by the periphery circuits in the path transistor can be saved, and the manufacturing cost of the flash memory apparatus can be lowered.

### BRIEF DESCRIPTION OF THE DRAWINGS

FIG. 1 is a circuit block diagram of a conventional flash memory apparatus;

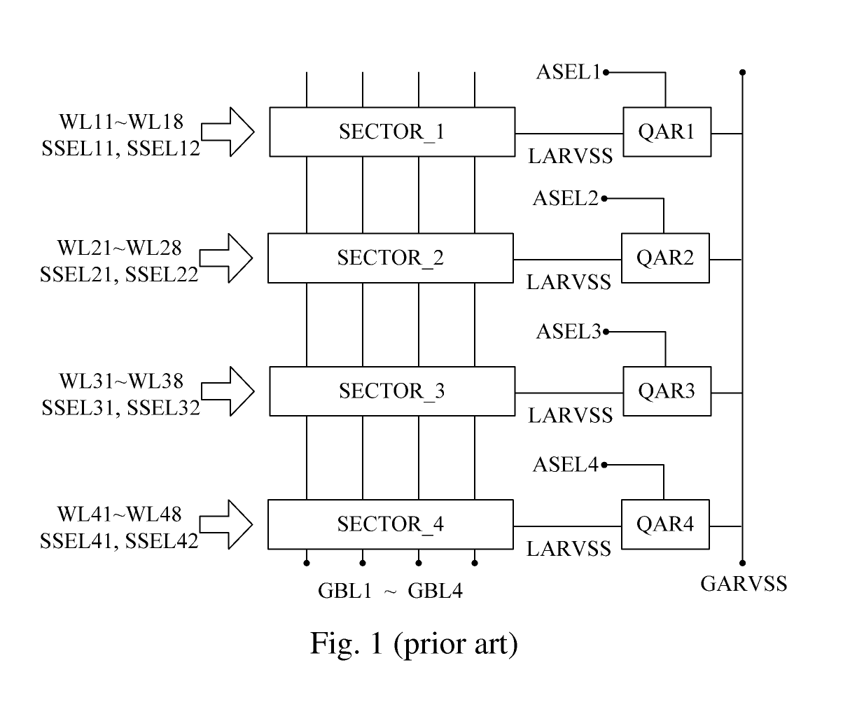

FIG. 2 is a circuit diagram of a memory sector as depicted in FIG. 1;

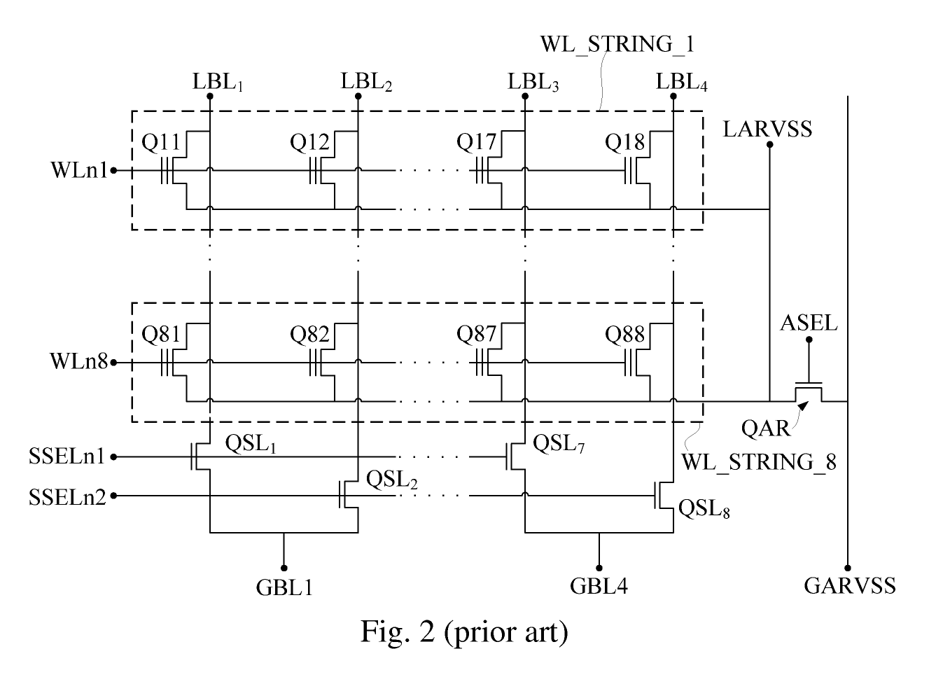

FIG. 3 is a layout diagram of a flash memory apparatus of the present invention; and

FIG. 4 is a partial circuit block diagram of a memory sector as depicted in FIG. 3.

### DETAILED DESCRIPTION

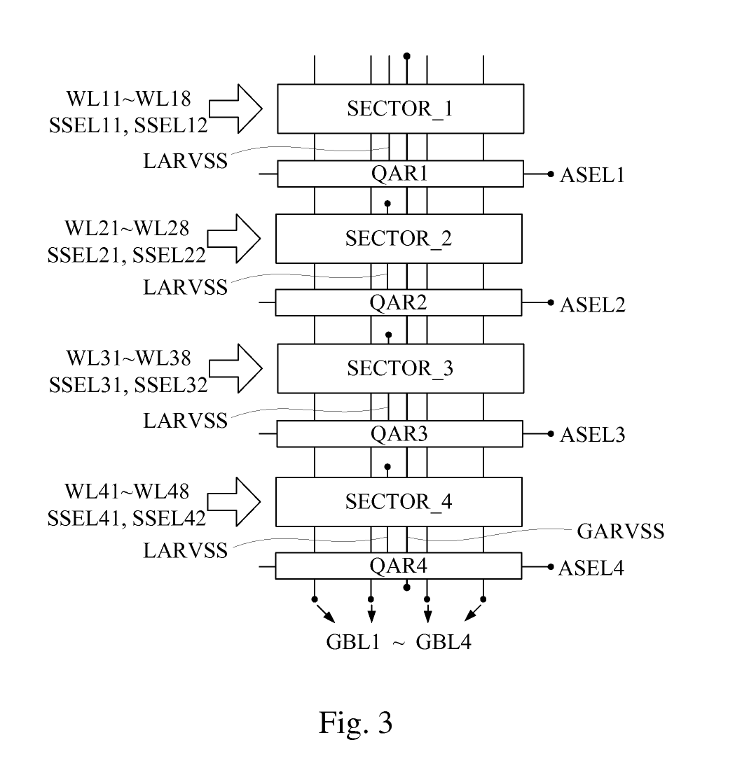

To reduce the layout area of a flash memory apparatus, the present invention provides a flash memory apparatus with a smaller layout area, and makes use of a blank area (which is an area without any electronic device installed therein) originally existed between memory sectors to install the path transistors, so as to save the area occupied by the peripheral circuits in the path transistors and improve the overall utility rate of the circuit area. With reference to FIG. 3 for a circuit block diagram of a in accordance with a flash memory apparatus preferred embodiment of the present invention, the flash memory apparatus 30 includes a plurality of memory sectors SECTOR_1˜SECTOR_4 and a plurality of path transistors QAR1˜QAR4 corresponding to the memory sectors SECTOR_1˜SECTOR_4 respectively, and each of the memory sectors SECTOR_1˜SECTOR_4 has a plurality of word lines WL1˜WL8, a plurality of select signal lines SSEL1, SSEL2 and a plurality of global bit lines GBL1˜GBL4. During layout, a plurality of local low voltage line LARVSS and a global low voltage line GARVSS are installed at different layers. For example, the plurality of local low voltage lines LARVSS are installed at an upper layer of a substrate, and the global low voltage line GARVSS is installed at a lower layer of the substrate.

In a preferred embodiment of the present invention, each path transistor is installed in an alginment direction of the memory sectors, and a portion of the path transistors are installed between two adjacent memory sectors, and the last memory sector corresponding to the path transistor is not installed between two adjacent memory sectors.

In an example as shown in FIG. 3, the path transistor QAR1 is installed between the memory sectors SECTOR_1, SECTOR_2, and a gate of the path transistor QAR1 is connected to a source of the sector select signal line ASEL1, and a source of the path transistor QAR1 is connected to the global low voltage line GARVSS, and a source of the path transistor QAR1 is connected to the local low voltage line LARVSS of the memory sector SECTOR_1. With the aforementioned installation, the global low voltage line GARVSS is installed at an angle with a difference of 90 across the gate of the path transistor QAR1.

The path transistor QAR2 is installed between the memory sectors SECTOR2, SECTOR3, and a gate of the path transistor QAR2 is connected to the sector select signal line ASEL2, and a source of the path transistor QAR2 is connected to the global low voltage line GARVSS, and a source of the path transistor QAR2 is connected to the local low voltage line LARVSS of the memory sector SECTOR_2. With the aforementioned installation, the global low voltage line GARVSS is installed at an angle with a difference of 90 degrees across the gate of the path transistor QAR2.

The path transistor QAR3 is installed between the memory sectors SECTOR_3, SECTOR_4, and a gate of the path transistor QAR3 is connected to the sector select signal line ASEL3, and a source of the path transistor QAR3 is connected to the global low voltage line GARVSS, and a source of the path transistor QAR3 is connected to the local low voltage line LARVSS of the memory sector SECTOR_3. With the aforementioned installation, the global low voltage line GARVSS is installed at an angle with a difference of 90 degrees across the gate of the path transistor QAR 3.

The path transistor QAR4 is installed at the memory sector SECTOR_4 but not between two adjacent memory sectors. A gate of the path transistor QAR4 is connected to the sector select signal line ASEL4, and a source of the path transistor QAR4 is connected to the global low voltage line GARVSS, and a source of the path transistor QAR4 is connected to the local low voltage line LARVSS of the memory sector SECTOR_4. With the aforementioned installation, the global low voltage line GARVSS is installed at an angle with a difference of 90 degrees across the gate of the path transistor QAR 4.

There is a blank originally existed between two memory sectors SECTOR1˜SECTOR4, and the present invention installs the path transistor QAR1˜QAR3 between two memory sectors SECTOR_1˜SECTOR_4, and the global low voltage line GARVSS is installed at an angle with a difference of 90 degrees across the gate of the path transistor QAR1˜QAR4. As a result, the flash memory apparatus 30 of the present invention can reduce the layout area significantly.

In addition, the sector select signal lines ASEL1˜ASEL4 are installed at the middle layer of the substrate, and the sector select signal lines ASEL1˜ASEL4 are installed at an angle with a difference of 90 degrees across the local low voltage line LARVSS and the global low voltage line GARVSS of the memory sectors SECTOR_1˜SECTOR4. The word lines WL1˜WL8 and the select signal lines SSEL1, SSEL2 can also be installed at the middle layer of the substrate, and the global bit lines GBL1˜GBL4 can be installed at the lower layer of the substrate. The word lines WL1˜WL8 and the select signal lines SSEL1, SSEL2 are installed at an angle with a difference of 90 degrees across the global bit lines GBL1˜GBL4, and the local low voltage line LARVSS and the global low voltage line GARVSS of the memory sectors SECTOR_1˜SECTOR4.

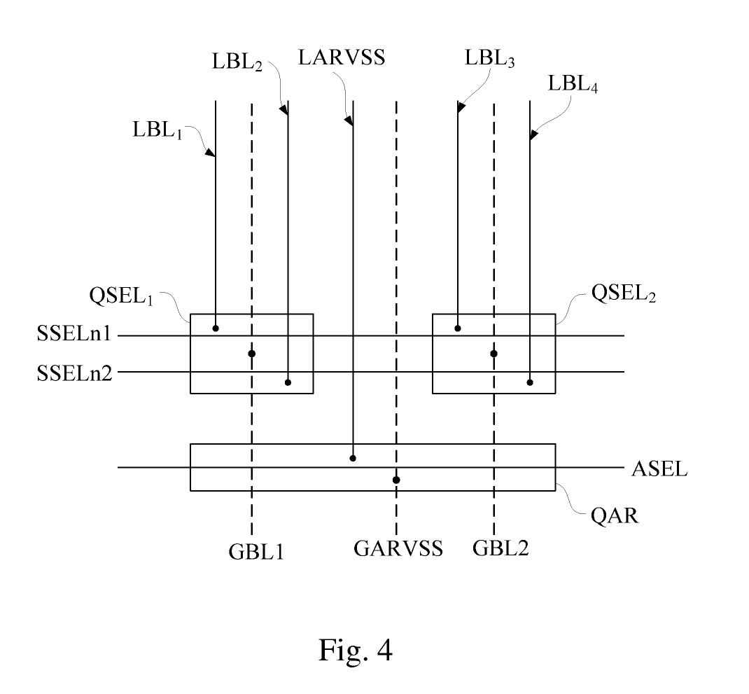

With reference to FIG. 4 for a partial circuit block diagram of a memory sector as depicted in FIG. 3, the circuit diagram is provided for the main purpose of showing the connection of the path transistor QAR, and thus the transistors for storing information in the memory sector are not drawn. The path transistor QAR is installed under the select transistors QSEL1, QSEL2. The local low voltage line LARVSS, and the local bit lines LBL1˜LBL4 are installed at the upper layer of the substrate, and the global low voltage line GARVSS and the global bit lines GBL1, GBL2 are installed at the lower layer of the substrate, and the sector select signal lines ASEL and the select signal lines SSEL1, SSEL2 are installed at the middle layer of the substrate. A source of the path transistor QAR is connected to the global low voltage line GARVSS, and a drain of the path transistor QAR is connected to the local low voltage line LARVSS. With the aforementioned installation, the global low voltage line GARVSS is installed at an angle with a difference of 90 degrees across the gate of the path transistor QAR.

In summation of the description above, a space is existed already when the present invention installs the path transistor between two memory sectors, and thus the original area of the memory unit will not be increased, and the global low voltage line is installed at an angle with a difference of 90 degrees across the gate of the path transistor, such that the area occupied by peripheral circuits in the path transistor can be saved, and the manufacturing cost of the flash memory apparatus can be lowered.

What is claimed is:

1. A flash memory apparatus, comprising:
a plurality of memory sectors, each having a local low voltage line; and
a plurality of path transistors, each corresponding to one of the memory sectors, and the path transistors being installed in an alignment direction of the memory sectors, and one of the path transistors being installed between two adjacent memory sectors, and a gate of said path transistor being connected to a sector select signal line, and a drain of said path transistor being connected to the local low voltage line of the corresponding memory sector, and a source of said path transistor being connected to a global low voltage line, and the global low voltage line being installed at an angle with a difference of 90 degrees across the gate.

2. The flash memory apparatus of claim 1, wherein the memory sector includes a plurality of word lines, a plurality of global bit lines and a plurality of select signal lines.

3. The flash memory apparatus of claim 2, wherein the memory sector includes a plurality of word strings and a plurality of select transistors composed of a plurality of transistors.

4. The flash memory apparatus of claim 1, wherein the flash memory apparatus is built at a substrate, and the local low voltage line and the global low voltage line are installed at different layers of the substrate.

5. The flash memory apparatus of claim 2, wherein the flash memory apparatus is built at a substrate, and the word lines and the select signal lines are installed at a second layer of the substrate, and the local low voltage line and the global low voltage line are installed at a first layer and a third layer of the substrate respectively.
